(19) United States
(12) Patent Application Publication
(10) Pub. No.: US 2009/0009134 A1
(43) Pub. Date: Jan. 8, 2009

(54) METHOD AND DEVICE FOR MEASURING INTERNAL RESISTANCE OF BATTERY

(75) Inventors: SHIH-FANG WONG, Tu-Cheng (TW); TSUNG-JEN CHUANG, Tu-Cheng (TW); JUN-WEI ZHANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/936,762

(22) Filed: Nov. 7, 2007

(30) Foreign Application Priority Data
Jul. 6, 2007 (CN) 200710201016.9

(51) Int. Cl. G01R 31/36; H01M 10/44; H01M 10/48; H02J 7/00

(52) U.S. Cl. 320/134

(57) ABSTRACT

A device for measuring an internal resistance of a battery includes a charging unit, a switch, a measuring unit, and a calculating unit. The charging unit is used for respectively charging the battery through a first resistor (R1) and a second resistor (R2). The switch is used for selectively connecting one of the first resistor and the second resistor to the battery. The measuring unit is used for measuring a first voltage (V1) across the first resistor and a second voltage (V2) across the second resistor. The calculating unit is used for calculating the internal resistance (Resr) via a following formula : Resr=(V2−V1)/(V1/R1-V2/R2). A related method for measuring the internal resistance of the battery is also provided.

### BACKGROUND OF THE INVENTION

1. Field of the Invention

The present invention relates to methods and devices for measuring performance of a battery, and especially to a method for measuring an internal resistance of the battery and a device implementing the same.

2. Description of Related Art

They are many different types of batteries, such as lithium batteries, manganese dry batteries, and alkaline dry batteries. Different batteries have different performances. The performance of each battery can be depicted with various technical indices, such as output voltage, internal resistance, and so on. The internal resistance can affect the performance of the battery.

Battery can be regarded as a combination of an ideal battery and an internal resistor connected in series. The ideal battery has no resistance, and the internal resistance of the battery correlates to the internal resistor. Each battery has a nominal voltage. Generally, when a current is discharged from a battery, one can consider the current as being discharged from an ideal battery in series with the internal resistor. The internal resistor will correspond to a drop voltage in the nominal voltage. Thus, the terminal voltage of the battery is determined by subtracting the “drop voltage” from the nominal voltage. The difference between the terminal voltage and the nominal voltage is proportional to the internal resistance. The larger the internal resistance of the battery, the less reliable is the nominal voltage. Therefore, in order to judge the performance of the battery, it is a necessity to measure the internal resistance of the battery.

Therefore, a method for measuring an internal resistance of a battery and a device implementing the method are desired.

### SUMMARY OF THE INVENTION

A device for measuring an internal resistance of a battery includes a charging unit, a measuring unit, a calculating unit, and a display unit. The charging unit charges the battery through one of a first resistor and a second resistor. The measuring unit measures a first voltage across the first resistor and a second voltage across the second resistor. The calculating unit calculates the internal resistance of the battery via the formula: Resr=(V2−V1)/(V1/R1−V2/R2), wherein, Resr is the internal resistance of the battery, R1 is the resistance of the first resistor, R2 is the resistance of the second resistor, V1 is the first voltage across the first resistor, and V2 is the second voltage across the second resistor. The display unit displays the internal resistance of the battery. A related method for measuring the internal resistance of the battery is also provided.

Other advantages and novel features will become more apparent from the following detailed description of preferred embodiments when taken in conjunction with the accompanying drawings.

### BRIEF DESCRIPTION OF THE DRAWINGS

FIG. 1 is a block diagram of a device for measuring an internal resistance of a battery in accordance with an exemplary embodiment.

FIG. 2 is a flowchart illustrating a method for measuring an internal resistance of the battery.

### DETAILED DESCRIPTION OF THE INVENTION

Reference will now be made to the drawings to describe the exemplary embodiment of the device and the method, in detail.

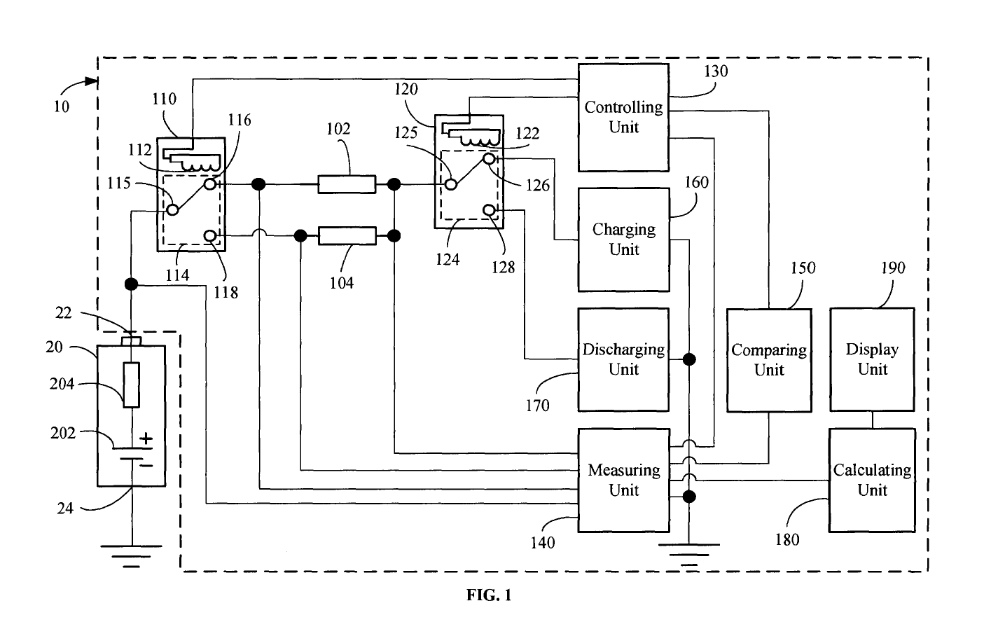

Referring to FIG. 1, a device 10 for measuring an internal resistance of a battery 20 in accordance with an exemplary embodiment is illustrated. The battery 20 can be regarded as a combination of an ideal battery 202 having no resistance and an internal resistor 204 having the internal resistance connected in series. The battery 20 has a positive terminal 22 and a negative terminal 24. The positive terminal 22 is coupled to the device 10, and the negative terminal 24 is connected to ground. The device 10 includes a first resistor 102, a second resistor 104, a first relay 110, a second relay 120, a controlling unit 130, a measuring unit 140, a comparing unit 150, a charging unit 160, a discharging unit 170, a calculating unit 180, and a display unit 190. The measuring unit 140, the charging unit 160, and the discharging unit 170 are connected to ground.

The first relay 110 is composed of an electromagnetic coil 112 and a first switch 114. The electromagnetic coil 112 is connected to the controlling unit 130. The first switch 114 can be a single pole, double throw (SPDT) switch and is configured for selectively connecting one of the first resistor 102 and the second resistor 104 to the positive terminal 22 of the battery 20. The first switch 114 has a common contact 115, a normally closed contact 116, and a normally open contact 118. The contact 115 is coupled to the positive terminal 22 of the battery 20. The contact 116 is connected to a first end of the first resistor 102 and the measuring unit 140. The contact 118 is connected to a first end of the second resistor 104 and the measuring unit 140.

A second end of the first resistor 102 and a second end of the second resistor 104 are both connected to the second relay 120. The second relay 120 is composed of an electromagnetic coil 122 and a second switch 124. The electromagnetic coil 122 is also connected to the controlling unit 130. The second switch 124 can be the SPDT switch and is configured for selectively connecting the two resistors 102, 104 to one of the charging unit 160 and the discharging unit 170. The second switch 124 has a common contact 125, a normally closed contact 126, and a normally open contact 128. The contact 125 is coupled to the two second ends of the two resistors 102, 104. The contact 126 is connected to the charging unit 160. The contact 128 is connected to the discharging unit 170.

The controlling unit 130 is configured for controlling the switching action of the first switch 114 and the second switch 124.

The measuring unit 140 is connected to the positive terminal 22 of the battery 20 for measuring a terminal voltage of the battery 20. Further, the measuring unit 140 is respectively connected to the ends of the resistors 102, 104 for measuring a first voltage across the first resistor 102 and a second voltage across the second resistor 104.

The comparing unit 150 is coupled to the measuring unit 140 and the controlling unit 130 and is configured for receiving the terminal voltage of the battery 20 and comparing the terminal voltage with a predetermined voltage. In detail, if the terminal voltage of the battery 20 is smaller than a predetermined voltage, the comparing unit 150 generates a first control signal and sends the first control signal to the controlling unit 130. The controlling unit 130 applies a low voltage to the electromagnetic coil 122 of the second relay 120 based on the first control signal. The second switch 124 thus remains electrically connected the charging unit 160 to the first resistor 102 and the second resistor 104. On the contrary, if the terminal voltage of the battery 20 is not smaller than the predetermined voltage, the comparing unit 150 generates a second control signal and sends the second control signal to the controlling unit 130. The controlling unit 130 applies a first high voltage to the electromagnetic coil 122, thus enabling the second switch 124 to electrically connect the discharging unit 170 to the first resistor 102 and the second resistor 104.

The charging unit 160 is coupled to the battery 20 through the two relays 110, 120 and one of the resistors 102, 104, and is configured for charging the battery 20. Under normal conditions, the switch 114 electrically connects the first resistor 102 to the battery 20, thus the charging unit 160 charges the battery 20 through the two relays 110, 120 and the first resistor 102. After measuring the first voltage across the first resistor 102, the measuring unit 140 generates a third control signal and sends the third control signal to the controlling unit 130. The controlling unit 130 applies a second high voltage to the electromagnetic coil 112 based on the third control signal, thus enabling the switch 114 to electrically connect the second resistor 104 to the battery 20.

The discharging unit 170 is coupled to the battery 20 through the two relays 110, 120 and one of the resistors 102, 104, and is configured for discharging the battery 20. Under normal conditions, the switch 114 electrically connects the first resistor 102 to the battery 20, thus the discharging unit 170 discharges the battery 20 through the two relays 110, 120 and the first resistor 102. After measuring the first voltage across the battery 20, the measuring unit 140 generates a fourth control signal and sends the fourth control signal to the controlling unit 130. The controlling unit 130 applies a third high voltage to the electromagnetic coil 112, thus enabling the switch 114 to electrically connect the second resistor 104 to the battery 20.

The calculating unit 180 is coupled to the measuring unit 140 for calculating the internal resistance of the battery 20 via the following formula: Resr=(V2−V1)/(V1/R1−V2/R2), wherein Resr is the internal resistance of the battery 20, R1 is the resistance of the first resistor 102, R2 is the resistance of the second resistor 104, V1 is the first voltage across the first resistor 102, and V2 is the second voltage across the second resistor 104. The calculating unit 180 is connected to the display unit 190 so as to send the internal resistance of the battery 20 to the display unit 190. The display unit 190 then displays a value of the internal resistance of the battery 20.

The working principle of the device 10 can be illustrates as follows. Take the charging mode as an example, the charging unit 160 charges the battery 20 through the first relay 110, the first resistor 102, and the second relay 120. The measuring unit 140 measures the first voltage V1 across the first resistor 102 and the terminal voltage Vt1 of the battery 20. After the measurement, the switch 114 connects the second resistor 104 to the battery 20. The charging unit 160 charges the battery 20 through the first relay 110, the second resistor 104, and the second relay 120. The measuring unit 140 measures the second voltage V2 across the second resistor 104 and the terminal voltage Vt2 of the battery 20. The internal resistance of the battery 20 can be calculated by the formula: Resr=(V2-V1)/(V1/R1-V2/R2), which is deduced from the following equations:

Vt1=Vbat+Resr(V1/R1)

Vt2=Vbat+Resr(V2/R2)

Vt1+V1=Vc

Vt2+V2=Vc

wherein:
Resr is the internal resistance of the battery 20;
Vc is the voltage of the charging unit 160;
Vbat is the voltage of the ideal battery 202;
R1 is the resistance of the first resistor 102;
R2 is the resistance of the second resistor 104.

The following formulas is deduced from the above equations.

Vbat+Resr(V1/R1)+V1=Vbat+Resr(V2/R2)+V2

Resr=(V2−V1)/(V1/R1−V2/R2)

The parameters V1, V2, R1, R2 are constants, so the internal resistance (Resr) of the battery 20 is calculated. It can be seen from the above formulas that the internal resistance of the battery 20 has no relationship with the voltage (Vc) of the charging unit 160 and the terminal voltage of the battery 20 (Vt1, Vt2). If the discharging unit 170 discharges the battery 20 through one of the first resistor 102 and the second resistor 104, the internal resistance (Resr) of the battery 20 can also be calculated from the above formulas.

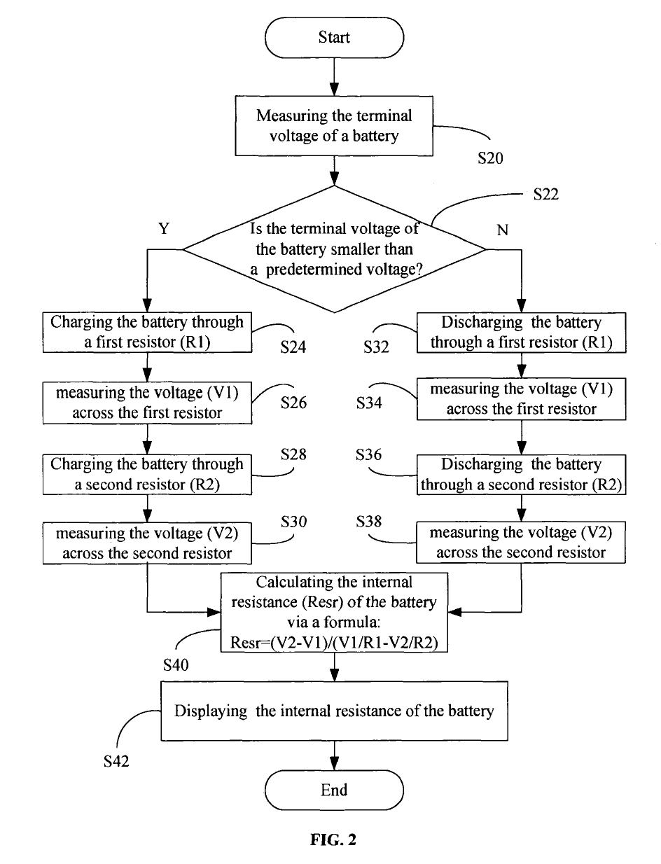

Referring to FIG. 2, a procedure of a method for measuring the internal resistance of the battery 20 is illustrated.

In step S20, the measuring unit 140 measures a terminal voltage of the battery 20.

In step S22, the comparing unit 150 compares the terminal voltage of the battery 20 with a predetermined voltage. The predetermined voltage is adjustable.

In step S24, if the terminal voltage of the battery 20 is smaller than the predetermined voltage, the charging unit 160 charges the battery 20 through the first relay 110, the first resistor 102, and the second relay 120.

In step S26, the measuring unit 140 measures the first voltage across the first resistor 102.

In step S28, when the measuring unit 140 has completed the measurement, the first switch 114 electrically connects the second resistor 104 to the battery 20. The charging unit 160 charges the battery 20 through the first relay 110, the second resistor 104, and the second relay 120.

In step S30, the measuring unit 140 measures the second voltage across the second resistor 104. The process proceeds to step S40.

In step S32, if the terminal voltage of the battery 20 is greater than the predetermined voltage, the second switch 124 connects the discharging unit 170 to the first resistor 102 and the second resistor 104. The discharging unit 170 discharges the battery 20 through the first relay 110, the first resistor 102, and the second relay 120.

In step S34, the measuring unit 140 measures the first voltage across the first resistor 102.

In step S36, when the measuring unit 140 has completed the measurement, the first switch 112 electrically connects the second resistor 104 to the battery 20. The discharging unit 170 discharges the battery 20 through the first relay 110, the second resistor 104, and the second relay 120.

In step S38, the measuring unit 140 measures the second voltage across the second resistor 104. Then the process proceeds to step S40.

In step S40, the calculating unit 180 calculates the internal resistance (Resr) of the battery 20 based on the following formula: Resr=(V2−V1)/(V1/R1−V2/R2) and sends the internal resistance of the battery 20 to the display unit 190.

In step S42, the display unit 190 displays the internal resistance of the battery 20.

It is understood that the invention may be embodied in various other forms without departing from the spirit thereof. Thus, the present examples and embodiments are to be considered in all respects as illustrative and not restrictive, and the invention is not to be limited to the details given above.

What is claimed is:

1. A device for measuring an internal resistance of a battery comprising:
a charging unit configured for respectively charging the battery through a first resistor and a second resistor;
a measuring unit configured for measuring a first voltage across the first resistor and a second voltage across the second resistor;
a calculating unit configured for calculating the internal resistance of the battery via the formula: Resr=(V2−V1 )/(V1/R1−V2/R2), wherein, Resr is the internal resistance of the battery, R1 is the resistance of the first resistor, R2 is the resistance of the second resistor, V1 is the first voltage across the first resistor, and V2 is the second voltage across the second resistor.

2. The device as claimed in claim 1, wherein the first resistor has two ends connected to the measuring unit, the second resistor has two ends connected to the measuring unit, and the calculating unit is electrically connected to the measuring unit.

3. The device as claimed in claim 2, further comprising a discharging unit configured for discharging the battery through one of the first resistor and the second resistor; a second relay configured for selecting one of the charging unit and the discharging unit to be electrically connected to the first resistor and the second resistor; a controlling unit configured for controlling the switching action of the second switch of the second relay.

4. The device as claimed in claim 3, wherein a common contact of the second relay is connected to the first resistor and the second resistor, a normally closed contact of the second relay is connected to the charging unit, a normally open contact of the second relay is connected to the discharging unit, and an electromagnetic coil of the second relay is connected to the controlling unit.

5. The device as claimed in claim 4, further comprising a comparing unit configured for comparing a terminal voltage of the battery with a predetermined voltage.

6. The device as claimed in claim 5, wherein the comparing unit connects the measuring unit to the controlling unit, the measuring unit measures the terminal voltage of the battery; if the terminal voltage of the battery is smaller than the predetermined voltage, the second switch of the second relay electrically connects the charging unit to the first resistor and the second resistor.

7. The device as claimed in claim 6, further comprising a first relay configured for selecting one of the first resistor and the second resistor to be electrically connected to the battery.

8. The device as claimed in claim 7, wherein a common contact of the first relay is connected to the battery, a normally closed contact of the first relay is connected to the first resistor, a normally open contact of the first relay is connected to the second resistor, and an electromagnetic coil of the first relay is connected to the controlling unit.

9. The device as claimed in claim 8, wherein the first switch of the first relay electrically connects the first resistor to the battery.

10. The device as claimed in claim 9, wherein the measuring unit is connected to the controlling unit; when the measuring unit has completed the measurement, the controlling unit controls the first switch of the first relay to electrically connect the second resistor to the battery.

11. The device as claimed in claim 5, wherein if the terminal voltage of the battery is larger than the predetermined voltage, the controlling unit controls the switch of the second relay to electrically connect the discharging unit to the first resistor and second resistor.

12. The device as claimed in claim 11, wherein the switch of the first relay electrically connects the first resistor to the battery.

13. The device as claimed in claim 12, wherein when the measuring unit has completed the measurement, the controlling unit controls the first switch of the first relay to electrically connect the second resistor to the battery.

14. The device as claimed in claim 1, further comprising a display unit configured for displaying the internal resistance of the battery.

15. A method for measuring an internal resistance of a battery, the method comprises the steps of:
measuring a terminal voltage of the battery;
comparing the terminal voltage of the battery with a predetermined voltage; connecting a charging unit with a first resistor and the battery, charging the battery through the first resistor, and measuring a voltage across the first resistor when the terminal voltage of the battery is smaller than the predetermined voltage;
connecting the charging unit with a second resistor and the battery, charging the battery through the second resistor, and measuring the voltage across the second resistor;
calculating the internal resistance of the battery via a formula: Resr=(V2−V1)/(V1/R1−V2/R2), wherein, Resr is the internal resistance of the battery, R1 is the resistance of the first resistor, R2 is the resistance of the second resistor, V1 is the voltage across the first resistor, and V2 is the voltage across the second resistor;
displaying the internal resistance of the battery.

16. The method as claimed in claim 15, wherein the predetermined voltage is adjustable.

17. A method for measuring an internal resistance of a battery, the method comprises the steps of:
measuring a terminal voltage of the battery;
comparing the terminal voltage of the battery with a predetermined voltage;
connecting the discharging unit with the first resistor and the battery, discharging the battery through the first resistor, and measuring the voltage across the first resistor when the terminal voltage of the battery is larger than the predetermined voltage;
connecting the discharging unit with the battery and the second resistor, discharging the battery through the second resistor, and measuring the voltage across the second resistor;
calculating the internal resistance of the battery via a formula: Resr=(V2−V1)/(V1/R1−V2/R2), wherein, Resr is the internal resistance of the battery, R1 is the resistance of the first resistor, R2 is the resistance of the second resistor, V1 is the voltage across the first resistor, and V2 is the voltage across the second resistor;
displaying the internal resistance of the battery.

18. The method as claimed in claim 17, wherein the predetermined voltage is adjustable.
